(19) United States
(12) Patent Application Publication
(10) Pub. No.: US 2006/0237778 A1
(43) Pub. Date: Oct. 26, 2006

(54) NON-VOLATILE SEMICONDUCTOR MEMORY CELL AND METHOD OF MANUFACTURING THE SAME

(76) Inventors: Mu-Yi Liu, Hsinchu (TW); Jongoh Kim, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/907,955

(22) Filed: Apr. 22, 2005

(51) Int. Cl. H01L 27/108

(52) U.S. Cl. 257/324

(57) ABSTRACT

A non-volatile memory cell. The non-volatile memory cell comprises a substrate with a first conductive type, a gate structure, at least two source/drain regions with a second conductive type and a buried channel region with the second conductive type. The gate structure is located on the substrate, and the source/drain regions are located in the substrate adjacent to both sides of the gate structure. Further, the buried channel region is located under the gate structure in the substrate, wherein the buried channel region is separated from the source/drain regions.

### BACKGROUND OF THE INVENTION

1. Field of Invention

The present invention relates to a semiconductor memory cell and the manufacturing method thereof. More particularly, the present invention relates to a non-volatile memory cell with a buried channel and the manufacturing method thereof.

2. Description of Related Art

The information storage mechanism in non-volatile memory cells such as EPROMs, EEPROMs and Flash EEPROMs is based on the possibility of having an electric charge trapped in a charge storage element. With the high demand of increasing semiconductor memory storage capacity per unit chip area, the current technology is improved to produce a memory cell which can be used to store more than one bit. Therefore, memory cells have been proposed having multiple threshold voltage levels. In such memory cells, for each value of electric charge, there corresponds a respective threshold voltage of the memory cell.

However, after performing several times of programming-and-erasing process cycle, it is inevitable for the memory cell to have carrier remain in the multiple charge storage element. Furthermore, it is not easy to well control the injection location of the hot electron or the hot holes in the multiple charge storage element after several times of the programming-and-erasing process cycle. Therefore, the threshold voltage of the injection charge carrier into the multiple charge storage element is greatly influenced by the residual charge. As a result, the threshold voltage distribution of the memory cell to become broader and broader even shifting away. Furthermore, the second bit effect further impacts the performance of the memory cell.

### SUMMARY OF THE INVENTION

Accordingly, at least one objective of the present invention is to provide a non-volatile memory cell capable of improving the immunity against the second bit effect and the affection of the residual carrier. Furthermore, the programming and erasing performance of the non-volatile memory cell according to the present invention is also improved.

At least another objective of the present invention is to provide a method of manufacturing a non-volatile memory cell having a buried channel region formed under a gate structure in the substrate. Because of the formation of the buried channel region, the ability for the non-volatile memory cell to resist the second bit effect is increased. Moreover, the non-volatile memory cell becomes more non-sensitive to the residual carrier after performing several times of programming-erasing process.

To achieve these and other advantages and in accordance with the purpose of the invention, as embodied and broadly described herein, the invention provides a non-volatile memory cell. The non-volatile memory cell comprises a substrate with a first conductive type, a gate structure, at least two source/drain regions with a second conductive type and a buried channel region with the second conductive type. The gate structure is located on the substrate, and the source/drain regions are located in the substrate adjacent to both sides of the gate structure. Further, the buried channel region is located under the gate structure in the substrate, wherein the buried channel region is separated from the source/drain regions.

In the present invention, the gate structure includes a gate dielectric layer on the substrate and a control gate on the gate dielectric layer. Further, the gate dielectric layer can be an oxide/nitride/oxide layer. Also, the second conductive type is N type when the first conductive type is P type. Alternatively, the second conductive type is P type when the first conductive type is N type. Moreover, a dopant concentration of the buried channel region of about of 5*10¹⁵˜5*10¹⁷ atoms/cm³ and a dopant concentration of the source/drain regions is about of 1*10²⁰˜1*10²¹ atoms/cm³.

The present invention also provides a non-volatile memory cell. The non-volatile memory cell comprises a substrate having a first conductive type, a multiple charge storage structure, a control gate, at least two source/drain regions with a second conductive type and a buried channel region with the second conductive type. The multiple charge storage structure is located on the substrate and the control gate is located on the multiple charge storage structure. Furthermore, the source/drain regions are located in the substrate adjacent to both sides of the gate structure and the buried channel region is located in the substrate between the source/drain regions, wherein the buried channel region is separated from the source/drain regions.

In the present invention, the multiple charge storage structure can be an oxide/nitride/oxide layer. Furthermore, the second conductive type is N type when the first conductive type is P type. On the other hand, the second conductive type is P type when the first conductive type is N type. Also, a dopant concentration of the buried channel region of about of 5*10¹⁵˜5*10¹⁷ atoms/cm³ and a dopant concentration of the source/drain regions is about of 1*10²⁰˜1*10²¹ atoms/cm³.

The present invention further provides a method of manufacturing a non-volatile memory cell for a substrate with a first conductive type. The method comprises steps of forming a doped region with a second conductive type in the substrate near the surface of the substrate and forming a gate structure over the substrate. Thereafter, the doped region is minified to be a buried channel region under the gate structure in the substrate by implanting a plurality of first dopants having the first conductive type into the substrate. Further, at least two source/drain regions having the second conductive type are formed in the substrate adjacent to the gate structure, wherein the source/drain regions are separated from the buried channel region.

In the present invention, the second conductive type is N type when the first conductive type is P type. Alternatively, the second conductive type is P type when the first conductive type is N type. Furthermore, the gate structure includes a multiple charge storage structure formed over the substrate and a control gate formed on the gate dielectric layer. More specifically, the multiple charge storage structure is made of oxide/nitride/oxide. Moreover, the first dopants can be boron-containing dopants. Also, a dopant concentration of the first dopants in the substrate is about of 1*10¹⁵ atoms/cm³ and a dopant concentration of the buried channel region of about of 5*10¹⁵˜5*10¹⁷ atoms/cm³. Also, the thickness of oxide/nitride/oxide is about 10˜150 A, 10˜200 A, and 10˜200 A, respectively. Further, the source/drain regions can be formed by implanting arsenic atoms into the substrate. The source/drain regions can be formed by performing an ion implantation process with an implanting energy about of 5˜30 Kev. A dopant concentration of the source/drain regions is about of 1*10²⁰˜1*10²¹ atoms/cm³.

Since the buried channel region is formed in the substrate between the source/drain regions and separated from the source/drain regions, the electric field of the junction between the substrate and the buried channel region is increased. Therefore, the efficiency of the programming and erasing processes is increased. Furthermore, because of the strengthened junction between the buried channel region and the substrate, the channel potential between the source/drain regions is dominated by the relatively high electric field between the buried channel region and the source/drain regions. Hence, the non-volatile memory cell becomes more non-sensitive to the residual carrier and the distribution of the threshold voltage of the non-volatile memory cell is well maintained even after performing several times of programming-erasing process. Also, the immunity of the non-volatile memory cell against the second bit effect is improved.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view showing a non-volatile memory cell according to one of the preferred embodiment of the invention.

FIG. 2A through FIG. 2D are schematic cross-sectional views of a method of manufacturing a non-volatile memory cell according to one of the preferred embodiment of the present invention.

### DESCRIPTION OF THE PREFERRED EMBODIMENTS

Reference will now be made in detail to the preferred embodiments of the present invention, example of which are illustrated in the accompanying drawings, in which like reference numerals are used to identify the same or similar parts.

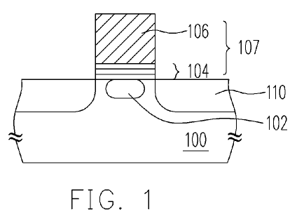

FIG. 1 is a cross-sectional view showing a non-volatile memory cell according to one of the preferred embodiment of the invention. As shown in FIG. 1, a non-volatile memory cell according to one of the preferred embodiment of the present invention comprises a substrate 100 with a first conductive type, a gate structure 107 including a multiple charge storage structure 104 and a control gate 106, at least two source/drain regions 110 with a second conductive type and a buried channel region 102 with the second conductive type. Notably, the second conductive type is N type when the first conductive type is P type. The substrate 100 with P type can be formed by, for example, implanting boron-containing dopants, B11, BF2 or indium into a substrate. Alternatively, the second conductive type is P type when the first conductive type is N type. The substrate 100 with N type can be formed by, for example, implanting phosphorous atoms, arsenic atoms or antimony atoms into a substrate.

More specifically, the multiple charge storage structure 104 is located on the substrate 100 and the control gate 106 is located on the multiple charge storage structure 104. It should be noticed that the multiple charge storage structure can be, for example, a gate dielectric layer formed from oxide/nitride/oxide. Furthermore, the source/drain regions 110 are located in the substrate 100 adjacent to both sides of the gate structure regions 107. Further, the buried channel region 102 is located under the gate structure 107 in the substrate 100 between the source/drain regions 110, wherein the buried channel region 102 is separated from the source/drain regions 110. When the first conductive type is N type and the second conductive type is P type, the buried channel region 102 can be, for example, formed by implanting boron-containing dopants, B₁₁, BF₂ or indium. When the first conductive type is type P and the second conductive type is N type, the buried channel region 102 can be, for example, formed by implanting arsenic atoms, phosphorous atoms or antimony atoms. Furthermore, when the first conductive type is N type and the second conductive type is P type, the source/drain region 110 can be, for example, formed by implanting boron-containing dopants, B₁₁, BF₂ or indium. When the first conductive type is type P and the second conductive type is N type, the source/drain region 110 can be, for example, formed by implanting arsenic atoms, phosphorous atoms or antimony atoms.

In addition, a dopant concentration of the buried channel region of about of 5*10¹⁵˜5*10¹⁷ atoms/cm³ and a dopant concentration of the source/drain regions is about of 1*10²⁰˜1*10²¹ atoms/cm³.

Since the buried channel region 102 possesses the second conductive type is different from that of the substrate 100, the electric field of the junction between the buried channel region 102 and the substrate 100 is strengthened. Hence, the channel potential between the source/drain regions 110 is dominated by the performance of the electric field of the junction between the source/drain regions 110. As a result, even though after performing several times of programming-erasing process cycle, the immunity of the non-volatile memory cell against the second bit effect is improved and the non-volatile memory cell becomes more non-sensitive to the residual carrier in the multiple charge storage structure. Therefore, the distribution profile of the threshold voltage of the non-volatile memory cell will not decay or broaden.

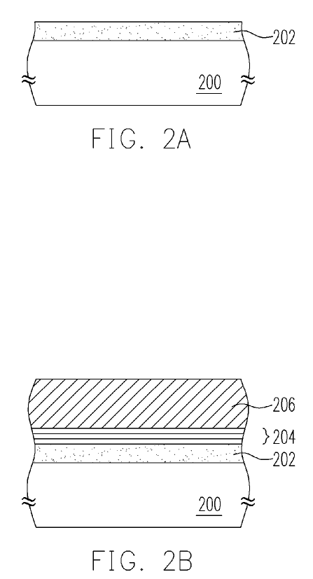

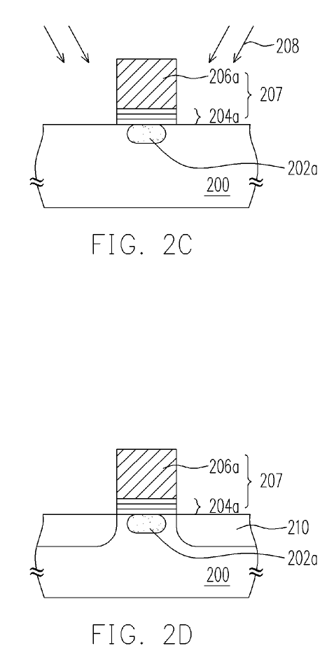

FIG. 2A through FIG. 2D are schematic cross-sectional views of a method of manufacturing a non-volatile memory cell according to one of the preferred embodiment of the present invention. As shown in FIG. 2A, a substrate 200 having a first conductive type is provided. A doped region 202 with a second conductive type is formed in the substrate 200 near the surface of the substrate 200. The method for forming the doped region 202 comprises a step of performing an ion implantation process by implanting dopants into the substrate 200. It should be noticed that the second conductive type is N type when the first conductive type is P type. Alternatively, the second conductive type is P type when the first conductive type is N type. More specifically, the dopant concentration of the doped region 202 is of about 5*10¹⁵˜5*10¹⁷ atoms/cm³. Moreover, when the first conductive type is type P and the second conductive type is N type, the doped region 202 can be, for example, formed by implanting arsenic atoms, phosphorous atoms or antimony atoms. Furthermore, when the first conductive type is N type and the second conductive type is P type, the doped region 202 can be, for example, formed by implanting boron-containing dopants, B₁₁, BF₂ or indium.

Then, as shown in FIG. 2B, a dielectric layer structure 204 and a conductive layer 206 are formed over the substrate 200 in sequence. The dielectric layer structure 204 can be, for example, made of oxide/nitride/oxide. Furthermore, the conductive layer can be, for example, formed from polysilicon.

As shown in FIG. 2C, the conductive layer 206 and the dielectric layer structure 204 are patterned to form a control gate 206a and a multiple charge storage structure 204a over the substrate 200 respectively. Notably, the control gate 206a and the multiple charge storage structure 204a together form a gate structure 207. Thereafter, the doped region 202 (shown in FIG. 2B) is minified to be a buried channel region 202a under the gate structure 207 in the substrate 100. More specifically, the method for minifying the doped region 202 comprises the step of performing an ion implantation process 208 to implant a plurality of dopants having the first conductive type into the substrate 200. Furthermore, the concentration in the substrate 200 is about of 5*10¹²˜5*10¹³ atoms/cm³ and the implantation energy is of about 20˜50 Kev. Moreover, when the first conductive type is type P and the second conductive type is N type, the dopants can be, for example, boron-containing dopants, B₁₁, BF₂ or indium. Furthermore, when the first conductive type is N type and the second conductive type is P type, the dopants can be, for example, arsenic atoms, phosphorous atoms or antimony atoms.

As shown in FIG. 2D, at least two source/drain regions 210 having the second conductive type are formed in the substrate 200 adjacent to the gate structure 207, wherein the source/drain regions 200 are separated from the buried channel region 202a.

Further, the source/drain regions 210 can be, for example, formed by performing an ion implantation process with an implanting energy about of 5˜30 Kev. A dopant concentration of the source/drain regions is about of 1*10²⁰˜1*10²¹ atoms/cm³. Furthermore, when the first conductive type is N type and the second conductive type is P type, the source/drain region 210 can be, for example, formed by implanting boron-containing dopants, B₁₁, BF₂ or indium. When the first conductive type is type P and the second conductive type is N type, the source/drain region 210 can be, for example, formed by implanting arsenic atoms, phosphorous atoms or antimony atoms.

Since the buried channel region 202a is formed in the substrate 200 between the source/drain regions 210 and separated from the source/drain regions 210, the electric field of the junction between the substrate and the buried channel region is increased. Therefore, the efficiency of the programming and erasing processes is increased and the injection capability in the ways of channel hot electrons and band-to-band-tunneling hot holes is relatively enhanced. Furthermore, because of the strengthened junction between the buried channel region 202a and the substrate 200, the channel potential between the source/drain regions 210 is dominated by the relatively high electric field between the buried channel region 202a and the source/drain regions 210. Hence, the non-volatile memory cell becomes more non-sensitive to the residual carrier and the distribution of the threshold voltage of the non-volatile memory cell is well maintained even after performing several times of programming-erasing process. Also, the immunity of the non-volatile memory cell against the second bit effect is improved.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A non-volatile memory cell, comprising:
a substrate having a first conductive type;
a gate structure located on the substrate;
at least two source/drain regions having a second conductive type located in the substrate adjacent to both sides of the gate structure; and
a buried channel region with the second conductive type located under the gate structure in the substrate, wherein the buried channel region is separated from the source/drain regions.

2. The non-volatile memory cell of claim 1, wherein the gate structure includes a gate dielectric layer on the substrate and a control gate on the gate dielectric layer.

3. The non-volatile memory cell of claim 1, wherein the gate dielectric layer can be an oxide/nitride/oxide layer.

4. The non-volatile memory cell of claim 1, wherein the second conductive type is N type when the first conductive type is P type.

5. The non-volatile memory cell of claim 1, wherein the second conductive type is P type when the first conductive type is N type.

6. The non-volatile memory cell of claim 1, wherein when the first conductive type is N type and the second conductive type is P type, the buried channel region can be a doped region with dopants B₁₁, BF₂ or indium.

7. The non-volatile memory cell of claim 1, wherein when the first conductive type is type P and the second conductive type is N type, the buried channel region can be a doped region with dopants arsenic atoms, phosphorous atoms or antimony atoms.

8. The non-volatile memory cell of claim 1, wherein when the first conductive type is N type and the second conductive type is P type, the source/drain regions can be a doped region with dopants B₁₁, BF₂ or indium.

9. The non-volatile memory cell of claim 1, wherein when the first conductive type is type P and the second conductive type is N type, the source/drain regions can be a doped region with dopants arsenic atoms, phosphorous atoms or antimony atoms.

10. A non-volatile memory cell, comprising:
a substrate having a first conductive type;
a multiple charge storage structure located on the substrate;
a control gate located on the multiple charge storage structure;
at least two source/drain regions having a second conductive type located in the substrate adjacent to both sides of the gate structure; and
a buried channel region with the second conductive type located in the substrate between the source/drain regions, wherein the buried channel region is separated from the source/drain regions.

11. The non-volatile memory cell of claim 10, wherein the multiple charge storage structure can be an oxide/nitride/oxide layer.

12. The non-volatile memory cell of claim 10, wherein the second conductive type is N type when the first conductive type is P type.

13. The non-volatile memory cell of claim 10, wherein the second conductive type is P type when the first conductive type is N type.

14. The non-volatile memory cell of claim 10, wherein when the first conductive type is N type and the second conductive type is P type, the buried channel region can be a doped region with dopants B₁₁, BF₂ or indium.

15. The non-volatile memory cell of claim 10, wherein when the first conductive type is type P and the second conductive type is N type, the buried channel region can be a doped region with dopants arsenic atoms, phosphorous atoms or antimony atoms.

16. The non-volatile memory cell of claim 10, wherein when the first conductive type is N type and the second conductive type is P type, the source/drain regions can be a doped region with dopants B₁₁, BF₂ or indium.

17. The non-volatile memory cell of claim 10, wherein when the first conductive type is type P and the second conductive type is N type, the source/drain regions can be a doped region with dopants arsenic atoms, phosphorous atoms or antimony atoms.

18. A method of manufacturing a non-volatile memory cell for a substrate with a first conductive type, comprising:
forming a doped region with a second conductive type in the substrate near the surface of the substrate;
forming a gate structure over the substrate;
minifying the doped region to be a buried channel region under the gate structure in the substrate by implanting a plurality of first dopants having the first conductive type into the substrate; and
forming at least two source/drain regions having the second conductive type in the substrate adjacent to the gate structure, wherein the source/drain regions are separated from the buried channel region.

19. The method of claim 18, wherein the second conductive type is N type when the first conductive type is P type.

20. The method of claim 18, wherein the second conductive type is P type when the first conductive type is N type.

21. The method of claim 18, wherein the gate structure includes a multiple charge storage structure formed over the substrate and a control gate formed on the gate dielectric layer.

22. The method of claim 21, wherein the multiple charge storage structure is made of oxide/nitride/oxide.

23. The method of claim 18, wherein the first dopants can be boron-containing dopants or indium dopants or arsenic dopants or phosphorous dopants or antimony dopants.

24. The method of claim 18, wherein the doped region can be formed by implanting arsenic atoms or phosphorous atoms or antimony atoms.

25. The method of claim 18, wherein the doped region can be formed by implanting B₁₁ or BF₂ or indium.

26. The method of claim 18, wherein the first dopants can be arsenic atoms or phosphorous atoms or antimony atoms.

27. The method of claim 18, wherein the first dopants can be B₁₁ atoms or BF₂ atoms or indium atoms.

28. The method of claim 18, wherein the source/drain regions can be formed by implanting arsenic atoms or antimony atoms into the substrate.

29. The method of claim 18, wherein the source/drain regions can be formed by implanting B₁₁ atoms or BF₂ atoms or indium atoms into the substrate.
